(19) United States
(12) Patent Application Publication
(10) Pub. No.: US 2010/0308415 A1
(43) Pub. Date: Dec. 9, 2010

(54) ANALOGUE THIN-OXIDE MOSFET

(75) Inventors: Rainer Herberholz, Cambridge (GB); David Vigar, Cambridge (GB); Sean Minehane, (US); Mark Redford, (US)

Correspondence Address: c/o Greenberg Traurig, LLP, 77 W. Wacker Drive, Suite 3100, Chicago, IL, 60601-1732, US

(73) Assignee: CAMBRIDGE SILICON RADIO LTD., Cambridge (GB)

(21) Appl. No.: 12/783,215

(22) Filed: May 19, 2010

(30) Foreign Application Priority Data
Jun. 5, 2009 (GB) 0909686.8
Jun. 24, 2009 (TW) 98121178

(51) Int. Cl. H01L 27/092; H01L 21/8238; G06F 17/50; B05C 11/00

(52) U.S. Cl. 257/369; 438/200; 716/110; 118/504; 257/E27.062; 257/E21.632

(57) ABSTRACT

A dual gate oxide CMOS technology providing three types of transistor; a thin oxide device, a thick oxide device, and a thin oxide device using the implant type of the thick oxide device for providing improved analogue performance.

### RELATED APPLICATIONS

This application claims the benefit of GB Application No. 0909686.8, filed on Jun. 5, 2009, and TW Application No. 98121178, filed on Jun. 24, 2009, the disclosures of which are incorporated herein by reference in their entirety.

### BACKGROUND

This invention relates to analogue thin-oxide MOSFETs, and in particular to analogue thin-oxide MOSFETs formed using dual-oxide CMOS technology.

Development of CMOS technologies has focussed on short channel devices to provide MOSFETs with high switching speed and high integration density. Although this development has led to improved performance in digital devices, the MOSFETs are not optimised for analogue performance, which can suffer due to the optimisation for digital operation.

CMOS technologies generally provide two types of MOSFET, a thin-oxide (core) MOSFET and a thick-oxide (IO) MOSFET. The core devices are optimised as above, while the IO devices are designed to provide a robust interface to external components at voltages higher than can be tolerated in the core devices.

The output resistance (variation of the output current as a function of the drain voltage) is an indicator of the analogue performance of MOSFETs. There are two main contributors to the output resistance; Channel Length Modulation (CLM) and Drain-induced Barrier Lowering (DIBL). For short-channel devices, CLM is the dominant factor in output resistance. CLM causes the width of the depletion region to increase with increasing drain voltage, which decreases the effective channel length. In long channel devices CLM becomes insignificant in comparison to DIBL. However, pocket implants used to suppress CLM in short channel devices degrade the output resistance of long channel devices by increasing DIBL.

To provide good device matching, constant current sources and low noise in analogue systems, channel lengths several times longer than the minimum provided by core devices are generally required.

Process options for multiple threshold voltages in core devices are generally provided, but each option requires additional masking steps to adjust the channel doping. Furthermore, beyond the 65 nm process node, pocket implants are generally used to define transistor type, rather than well and channel implants. Different device types therefore have very similar long-channel threshold voltages and so low-threshold short-channel devices are not useful to increase the available voltage headroom in long-channel devices for analogue circuits.

The IO transistors of a process provide increased headroom if they are used as an analogue device at a higher operating voltage than the core, and they generally have lighter or no pocket implants. However, RF circuits may require transistors with a combination of analogue performance and the higher switching speed of the core devices.

Blocking LDD implants can be utilised to improve the output resistance at high drain voltages, but the poor link-up between the inversion channel and drain area degrades resistance in linear operation and increases the drain saturation voltage, thereby limiting the usefulness of such a route to an analogue transistor.

Additional types of transistor can be provided by the use of additional processing steps. However, such an approach is expensive and development often lags behind leading-edge CMOS technologies.

There is therefore a need for a means to provide an improved performance analogue transistor, which addresses some or all of the shortcomings of prior techniques.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Where references are made to mask properties, the term ‘open’ or ‘opening’ is used to indicate that during wafer processing, the mask causes the creation of a related feature (i.e. oxide or implant) at that location. This term is used for convenience and is not intended to indicate that the physical mask has an actual opening, but is rather indicative of the function of the area of the mask.

A mask set for the manufacture of a dual gate oxide CMOS integrated circuit, comprising a first mask for the definition of LDD implants in a thick gate oxide transistor, a second mask for the definition of gate oxides, wherein the first mask is open for the definition of LDD implants at a first site and the second mask is closed for the definition of a thin gate oxide at that first site, for the formation of a transistor in the integrated circuit at that first site.

The mask set may further comprise a third mask for the definition of LDD implants in a thin gate oxide transistor.

The second mask may be closed for the definition of a thin gate oxide at a second site and the third mask is open for the definition of LDD implants at that second site, for the formation of a conventional thin-oxide transistor at that site, and the first mask may be open for the definition of LDD implants at a third site and the second mask is open for the definition of a thick gate oxide at that third site, for the formation of a conventional thick-oxide transistor at that site. For the avoidance of doubt, the first and third masks are not opened at the same site.

There is also provided a method for the manufacture of a dual-oxide CMOS integrated circuit, comprising the steps of forming a thin-oxide transistor using a first implant type and a first oxide configuration, forming a thick-oxide transistor using a second implant type and a second oxide configuration, and forming a third type of transistor using the first oxide configuration and the second implant type.

There is also provided a method for the manufacture of a dual gate oxide CMOS integrated circuit utilising the mask set described above, comprising the steps of implanting LDD implants at the first site using the first mask, and defining a thin oxide layer using the second mask at the first site.

There is also provided a dual gate oxide CMOS integrated circuit, comprising at least one thin-oxide transistor comprising a gate oxide having a first configuration and a first implant type, at least one thick-oxide transistor comprising a gate oxide having a second configuration and a second implant type, and at least one further transistor comprising a gate oxide of the first configuration and implants of the second type.

The first gate oxide configuration may be a thin-oxide gate principally for high speed performance or lower supply voltage and the second type of gate oxide may be a thick oxide gate principally for IO devices or higher supply voltage.

There is also provided a method of designing a dual oxide CMOS integrated circuit using a CMOS technology, the CMOS technology comprising a thin gate oxide transistor utilising a first gate oxide configuration and a first implant type, and a thick gate oxide transistor utilising a second gate oxide configuration and a second implant type, the method comprising the step of defining at least one transistor using the first gate oxide configuration and the second implant type.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 shows a schematic diagram of three types of transistor provided by a modified CMOS technology;

FIG. 2 shows a schematic diagram of a mask set according to a modified CMOS technology;

FIG. 3 shows a graph of threshold voltage against channel length;

FIG. 4 shows IDsat and IDlin graphs for varying threshold voltages;

FIG. 5 shows gds graphs for varying channel lengths;

FIG. 6 shows gds graphs for varying drain voltages;

FIG. 7 shows a graph of intrinsic gain against overdrive voltage; and

FIG. 8 shows a graph exhibiting the matching of devices.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

It will be understood that the phrase ‘CMOS technology’ is used herein to refer to a defined set of processes and options for the design and manufacture of CMOS devices. The phrase is not intended to be restrictive and should be read to also include BiCMOS and other process variants to which the following disclosure also applies.

The use of the word implant or implant condition is used in this disclosure to refer to any method by which dopants are introduced into CMOS devices, for example, but not limited to, ion implantation. The methods and techniques described herein are independent of the methods used to introduce dopants.

Where references are made to mask properties, the term ‘open’ or ‘opening’ is used to indicate that during wafer processing, the mask causes the creation of a related feature (i.e. oxide or implant) at that location. This term is used for convenience and is not intended to indicate that the physical mask has an actual opening, but is rather indicative of the function of the area of the mask.

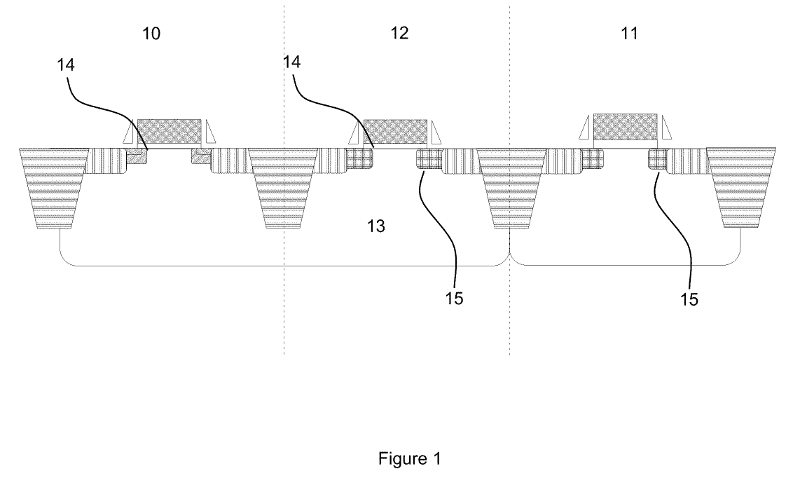

It has now been shown that a transistor having an improved performance can be fabricated by combining certain features from thin and thick oxide transistors in a dual oxide CMOS technology. FIG. 1 shows a cross section of conventional thin-oxide (core) 10 and thick-oxide (IO) MOSFET devices 11, together with an analogue thin-oxide transistor (AVT) 12 according to the current disclosure. The AVT is formed in the core p-well 13, and utilises the thin gate-oxide 14 of the core devices, but uses the LDD implants 15 of the IO device.

This disclosure therefore relates to an extension of a conventional CMOS technology. The conventional CMOS technology provides two types of transistor, whereas the modified CMOS technology provides three types of transistor. Where the term conventional CMOS technology is used herein it is used to describe a technology providing base devices from which features may be combined according to the current disclosure. This description has been given in the context of a technology providing two transistor types for different supply voltages, but the conventional CMOS technology to which this disclosure is applied may provide more than two transistor types. Similarly, the disclosure applies to all modifications and variants of the basic CMOS processes.

The provision of the AVT transistor 12 by the modified CMOS technology does not require any additional processing or development beyond the core 10 and IO 11 devices provided by the conventional CMOS technology. The AVT transistor can therefore be provided without additional cost or manufacturing cycle time.

The AVT transistor may be provided by an extension of the Process Design Kit (PDK) in relation to the CMOS technology. The provision of new rules, design options and models allow the use of the new AVT transistor within designs using the modified CMOS technology. As explained previously, the provision of the new transistor type does not require additional processing steps and so the wafer manufacturing process remains conventional, although new mask layouts are created by the new rules which lead to the definition of new, previously unavailable, combinations of devices in the ICs formed according to the modified CMOS technology.

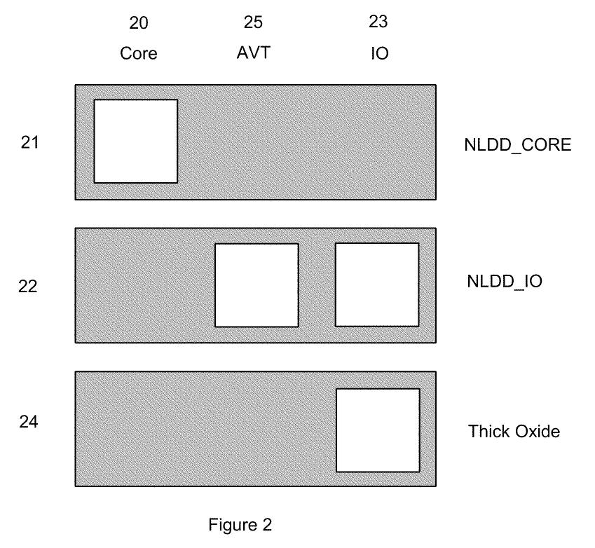

FIG. 2 shows a schematic diagram of a mask set for defining thin-oxide core, AVT and thick-oxide IO transistors according to the modified CMOS technology. Openings in the mask show devices for which that process step is applied to for a particular device. As explained above, the word opening is not used to indicate a physical opening, but rather that that process step is applied to the indicated device. The active area, well & channel implants, gate-electrode and N⁺ or P+ masks are not shown as those steps are independent of the subject of this disclosure.

For the core device 20 the NLDD_CORE implant mask 21 (LDD/pocket for thin gate oxide devices) is open but the NLDD_IO implant mask 22 (LDD/pocket mask for thick gate oxide devices) is closed. In contrast the NLDD_IO implant mask 22 is open for the IO device 23, but the NLDD implant mask 21 is closed. The thick oxide mask 24 is open only for the thick-oxide IO device 23. For the avoidance of doubt, for devices where the thick oxide mask is closed, a thin oxide is assumed to be present.

For the conventional devices, the NLDD_CORE mask 21 can therefore be written logically as [N+ AND ACTIVE-AREA NOT THICK-OXIDE], and the NLDD_IO mask 22 can be written logically as [N+ AND ACTIVE-AREA AND THICK-OXIDE].

The AVT device 25 utilises a new combination of features for the NLDD_IO mask 22, and introduces the combination [N+ AND ACTIVE-AREA AND AVT_LDD], where AVT_LDD is a marker layer marking AVT devices.

The AVT device of the current disclosure is thus obtained by new features of the PDK utilised in the design of integrated circuits and in the mask manufacture process. The modified CMOS technology provides new combinations of mask openings to provide the AVT device without adding process steps. An AVT device is thus characterised by utilising a combination of features from the core and IO devices provided by the conventional CMOS technology.

ICs utilising the modified CMOS technology incorporating the AVT device may be characterised by presence of devices sharing features with more than one other type of device in the chip, in particular sharing an oxide layer with one type of device, and implants with another type of device. More particularly, the AVT device shares an oxide layer with a thin-oxide core transistor and implants with a thick-oxide IO transistor. In a further embodiment a transistor may share an oxide layer with a thick-oxide IO transistor and implants with a thin-oxide core transistor. Such a transistor may be defined using the techniques described above with modifications to the definition of the masks and processes to apply the relevant oxide and implants.

Data is presented below demonstrating the expected performance of AVT devices. Unless otherwise stated FIGS. 2-7 below relate to a foundry 40 nm low-power CMOS technology using 1.1V thin-oxide devices and 2.5 thick-oxide devices

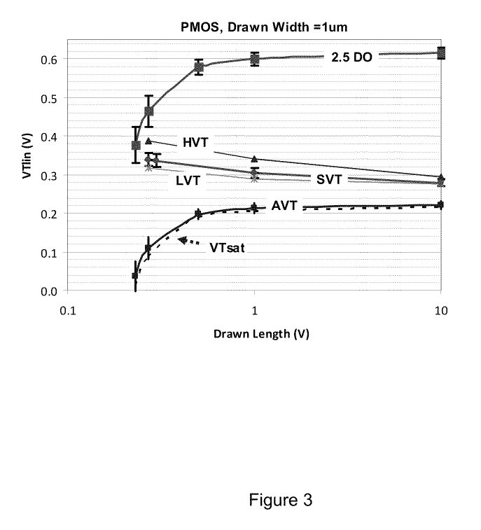

FIG. 3 shows a graph comparing the VTlin of thin-oxide core devices (LVT—Low Threshold Voltage, SVT—Standard Threshold Voltage, HVT—High Threshold Voltage), thick-oxide IO devices and an AVT MOSFET according to the current disclosure, for varying drawn lengths.

At channel lengths significantly larger than the minimum length, the LVT, SVT and HVT devices all have very similar threshold voltages due to the use of pocket implants to generate the variants as opposed to channel implants. The pocket implants also lead to the reverse-short channel effect seen in the graph.

The AVT device provides a lower threshold voltage and retains the VT roll-off of the IO device. The better gate control provided by the use of a thin-oxide gives a smaller difference in VT between L=10 m and 0.23 m compared to the IO device.

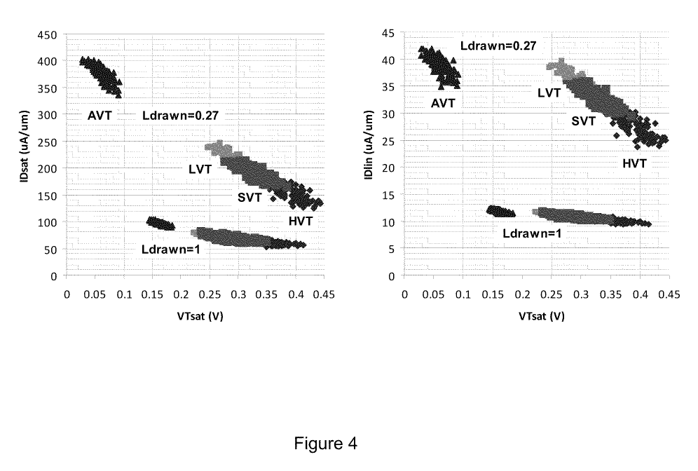

FIG. 4 shows plots of IDₛₐₜ and IDₗᵢₙ for the core, IO and AVT devices as described previously in relation to FIG. 2. The IDₛₐₜ values for the AVT follow the general trend of the core devices while showing lower IDₗᵢₙ compared to an extrapolation of the core devices. This is caused by the higher resistance of the LDD implants from the IO device used in the AVT.

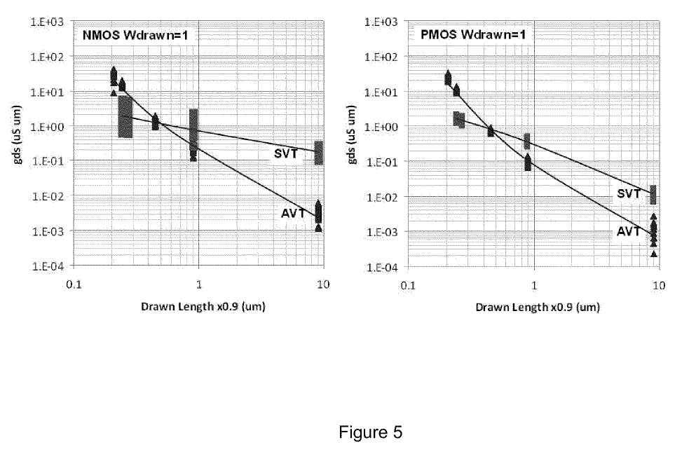

FIG. 5 shows plots of gds against drawn length for the SVT and AVT devices described previously. The SVT device has lower gds at short lengths due to better control of length modulation, but the AVT has lower gds for longer devices due to reduced DIBL.

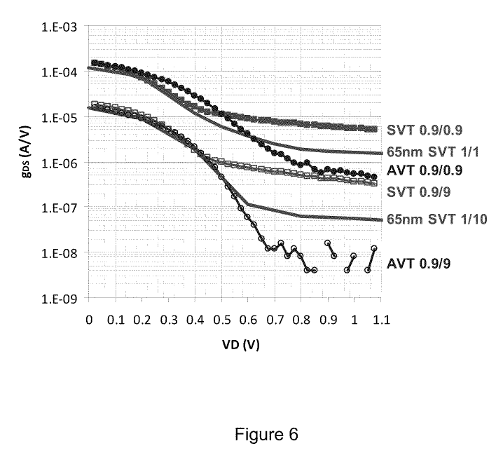

FIG. 6 shows a graph of gds against VD for AVT and SVT devices. The data for the 65 nm process node shows the degradation of a conventional thin-oxide core device at 40 nm compared to the 65 nm device, highlighting the need for the AVT device provided by the modified CMOS technology.

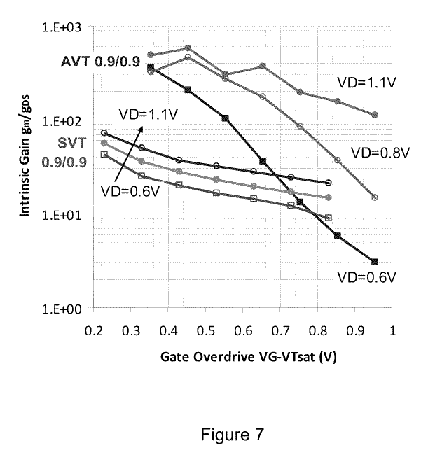

FIG. 7 shows intrinsic gain against gate overdrive voltage for SVT and AVT devices. The improvement of the intrinsic gain follows from the improved output conductance discussed above, while the differences in transconductance (gm) are minor. The improvement over SVT devices is most pronounced at small gate overdrive voltages, which is beneficial in analogue circuits.

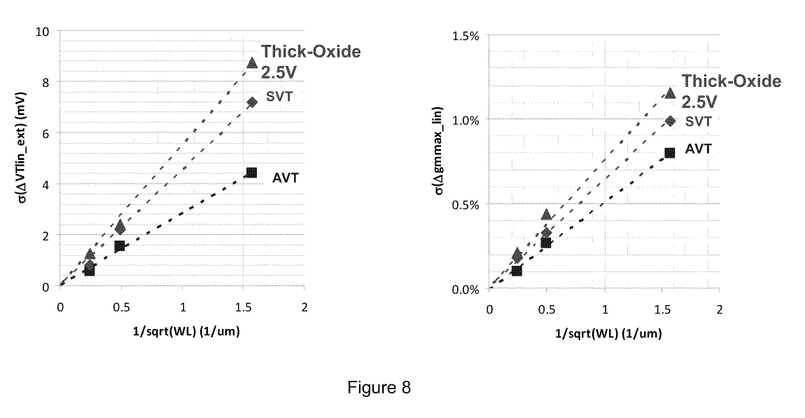

FIG. 8 shows a Pelgrom plot for the AVT device, showing improved device mismatch for the AVT compared to both SVT thin-oxide core devices and thick-oxide IO devices.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

What is claimed is:

1. A dual gate oxide CMOS integrated circuit, comprising
at least one thin-oxide transistor comprising a gate oxide having a first configuration and a first implant type,
at least one thick-oxide transistor comprising a gate oxide having a second configuration and a second implant type, and
at least one further transistor comprising a gate oxide of the first configuration and implants of the second type.

2. A dual gate oxide CMOS integrated circuit according to claim 1, wherein the first gate oxide configuration is a thin-oxide gate principally for high speed performance or lower supply voltage and the second type of gate oxide is a thick oxide gate principally for IO devices or higher supply voltage.

3. A mask set for the manufacture of a dual gate oxide CMOS integrated circuit, comprising
a first mask for the definition of LDD implants in a thick gate oxide transistor,
a second mask for the definition of gate oxides,
wherein the first mask is open for the definition of LDD implants at a first site and the second mask is closed for the definition of a thin gate oxide at that first site, for the formation of a transistor in the integrated circuit at that first site.

4. A mask set according to claim 3, further comprising
a third mask for the definition of LDD implants in a thin gate oxide transistor.

5. A mask set according to claim 4, wherein
the second mask is closed for the definition of a thin gate oxide at a second site and the third mask is open for the definition of LDD implants at that second site, for the formation of a conventional thin-oxide transistor at that site, and
the first mask is open for the definition of LDD implants at a third site and the second mask is open for the definition of a thick gate oxide at that third site, for the formation of a conventional thick-oxide transistor at that site.

6. A method for the manufacture of a dual-oxide CMOS integrated circuit, comprising the steps of
forming a thin-oxide transistor using a first implant type and a first oxide configuration,
forming a thick-oxide transistor using a second implant type and a second oxide configuration, and
forming a third type of transistor using the first oxide configuration and the second implant type.

7. A method for the manufacture of a dual gate oxide CMOS integrated circuit utilising the mask set of claim 3, comprising the steps of
implanting LDD implants at the first site using the first mask, and
defining a thin oxide layer using the second mask at the first site.

8. A method of designing a dual oxide CMOS integrated circuit using a CMOS technology, the CMOS technology comprising a thin gate oxide transistor utilising a first gate oxide configuration and a first implant type, and a thick gate oxide transistor utilising a second gate oxide configuration and a second implant type, the method comprising the step of
defining at least one transistor using the first gate oxide configuration and the second implant type.
